(19) United States
(12) Patent Application Publication
(10) Pub. No.: US 2011/0309438 A1
(43) Pub. Date: Dec. 22, 2011

(54) SEMICONDUCTOR APPARATUS AND MANUFACTURING METHOD THEREOF

(75) Inventors: Hisao ICHIJO, Osaka-shi (JP); Alberto O. Adan, Osaka-shi (JP); Kazushi Naruse, Osaka-shi (JP)

(73) Assignee: SHARP KABUSHIKI KAISHA, Osaka (JP)

(21) Appl. No.: 13/161,897

(22) Filed: Jun. 16, 2011

(30) Foreign Application Priority Data
Jun. 18, 2010 (JP) 2010-139931

(51) Int. Cl. H01L 29/78; H01L 21/336

(52) U.S. Cl. 257/335; 438/286; 257/E29.256; 257/E21.409

(57) ABSTRACT

The semiconductor apparatus according to the present invention includes: a second-conductivity-type first diffusion region formed on the semiconductor layer; a first-conductivity-type second diffusion region formed in the first diffusion region; a second-conductivity-type first high concentration diffusion region and a first-conductivity-type second high concentration diffusion region formed in the second diffusion region; a second-conductivity-type third high concentration diffusion region, separated by a given distance from the second diffusion region, in the first diffusion region; and a gate electrode formed above and between the first high concentration diffusion region and third high concentration diffusion region, with a gate insulation film interposed therebetween, where the gate electrode is formed overlapping the first high concentration diffusion region, and the gate electrode is electrically connected with the first high concentration diffusion region and second high concentration diffusion region, at the same potential.

This nonprovisional application claims priority under 35 U.S.C. §119(a) to Patent Application No. 2010-139931 filed in Japan on Jun. 18, 2010, the entire contents of which are hereby incorporated by reference.

### BACKGROUND OF THE INVENTION

1. Field of the Invention

The present invention relates to: a semiconductor apparatus, such as a high voltage diode (for resisting high voltage), which is a device for rectification; and a method for manufacturing the semiconductor apparatus.

2. Description of the Related Art

A high voltage diode, such as a conventional semiconductor apparatus of this type, fills an important role in the field of power management, and is a typical diode device for rectification, such as a boost converter, a buck converter and a battery charger, which is formed in a monolithic integrated circuit.

However, when a high voltage diode is formed in an integrated circuit, there is a problem of the occurrence of a leakage current to a substrate during the use in the forward direction due to the influence of a parasitic bipolar transistor near a joint part, resulting in an increase of power consumption.

Hereinafter, a conventional high voltage diode 100 described in Reference 1 will be described in detail with reference to FIGS. 18(a) and 18(b).

FIG. 18(a) is a longitudinal cross sectional view schematically illustrating a conventional high voltage diode disclosed in Reference 1. FIG. 18(b) is a diagram describing current paths I1 and I2 as well as a substrate leakage current under a forward bias in the longitudinal cross sectional view of FIG. 18(a).

As illustrated in FIG. 18(a), a conventional high voltage diode 100 includes: a P-type semiconductor substrate 101; an N-type semiconductor layer 102 formed on the P-type semiconductor substrate 101; and in the N-type semiconductor layer 102, a first P-type diffusion region 103 functioning as an anode region, a second P-type diffusion region 104 electrically connected with the P-type diffusion region 103, and an N-type diffusion region 107 formed separately from the P-type diffusion region 103.

In addition, a high concentration P-type diffusion region 106 is formed in the P-type diffusion region 103. Further, a high concentration N-type diffusion region 105 is formed in the P-type diffusion region 104, and a high concentration N-type diffusion region 105A is formed in the N-type diffusion region 107.

An anode electrode is formed above the high concentration P-type diffusion region 106, and a cathode electrode is formed above the high concentration N-type diffusion region 105. The high concentration N-type diffusion region 105A is electrically connected with the high concentration N-type diffusion region 105 by the cathode electrode at the same electric potential.

In general, a PN junction diode is formed by the PN junction of an anode region constituted of a P-type diffusion region and a cathode region constituted of an N-type diffusion region. The PN junction diode has a so-called rectifying action, where a forward direction current flows from the anode region to the cathode region under a forward bias, and the current is stopped under a reverse bias.

In the conventional high voltage diode 100, under a reverse bias, the length L illustrated in FIG. 18(a), and the profile of the P-type diffusion region 103 and the P-type diffusion region 104 are adjusted, so that resistance to high voltage can be achieved and a current under a reverse bias can be favorably stopped.

On the other hand, under a forward bias, as illustrated in FIG. 18(b), a positive power source is connected to the anode high concentration P-type diffusion region 106, and the cathode high concentration N-type diffusion region 105 and high concentration N-type diffusion region 105A are connected to ground. As a result, there lies a current path I1 starting from the high concentration P-type diffusion region 106 via the first P-type diffusion region 103 and the second P-type diffusion region 104 to the high concentration N-type diffusion region 105; and there also lies a current path 12 starting from the high concentration P-type diffusion region 106 via the first P-type diffusion region 103, the N-type semiconductor layer 102 and the N-type diffusion region 107, to the high concentration N-type diffusion region 105A.

In this structure, a parasitic PNPTr is formed which is constituted of a P-type diffusion region (first P-type diffusion region 103, second P-type diffusion region 104 and high concentration P-type diffusion region 106; emitter) of the anode region, the N-type semiconductor layer 102 (base), and the P-type semiconductor substrate 101 (collector). Although there is no problem with the current path 11, the impurity concentration of the N-type semiconductor layer 102 is low and the electric potential of the N-type semiconductor layer 102 becomes forward biased with respect to the P-type diffusion region of the anode region due to the current path 12. As a result, there exists a problem to be solved, where the parasitic PNPTr is turned on and a substrate leakage current flows into the P-type semiconductor substrate 101.

As illustrated in FIG. 18(b), in order to suppress the substrate leakage current under a forward bias in the conventional structure, it is conceivable to increase the impurity concentration of the N-type semiconductor layer 102 or to increase the thickness of the N-type semiconductor layer 102. In general, the N-type semiconductor layer 102 is also used by another device. Thus, considering a large influence to such another device, these ideas are difficult to realize. The increase in the substrate leakage current will also increase power consumption and cause the substrate electric potential to fluctuate unstably, causing a malfunction.

Thus, for the purpose of suppressing a substrate leakage current during a forward bias, Reference 2 discloses another means.

Hereinafter, a conventional high voltage diode 200 described in Reference 2 will be described with reference to FIG. 19.

FIG. 19 is a longitudinal cross sectional view schematically illustrating a sectional structure of an essential part of the conventional high voltage diode disclosed in Reference 2.

As illustrated in FIG. 19, a conventional high voltage diode 200 includes: a P-type semiconductor substrate 201; an N-type buried diffusion region 208 formed on the P-type semiconductor substrate 201; and a P-type semiconductor layer 202 formed further thereon. A P-type diffusion region 203 functioning as an anode region, and an N-type diffusion region 207 formed separately from the P-type diffusion region 203 are included in the P-type semiconductor layer 202.

In addition, an N-type sinker region 209 is included, which is formed separately from the P-type diffusion region 203 and is connected with the N-type buried diffusion region 208 at the bottom.

A P-type diffusion region 204 is further included, which is formed between the N-type diffusion region 207 and the N-type buried diffusion region 208.

A high concentration P-type diffusion region 206 is further formed in each P-type diffusion region 203. In addition, a high concentration N-type diffusion region 205 is formed in the N-type diffusion region 207. A high concentration N-type diffusion region 205A is further formed in each N-type sinker region 209.

An anode electrode is formed on the high concentration P-type diffusion region 206, and a cathode electrode is formed on the high concentration N-type diffusion region 205. The high concentration N-type diffusion region 205A is electrically connected with the high concentration N-type diffusion region 205 by the cathode electrode at the same electric potential.

A gate electrode 210 is further formed in between the anode region and the cathode region, for the purpose of resisting high voltage during a reverse bias. The anode electrode and the gate electrode 210 are electrically connected with each other at the same potential.

In the conventional high voltage diode 200, under a reverse bias, the length L illustrated in FIG. 19 and the profile of the N-type diffusion region 207 are adjusted, so that resistance to high voltage can be achieved and a current under a reverse bias can be favorably stopped.

On the other hand, as illustrated in FIG. 19, the current path under a forward bias starts from the high concentration P-type diffusion region 206 via the first P-type diffusion region 203, the P-type semiconductor layer 202 and the N-type diffusion region 207 further to the high concentration N-type diffusion region 205.

In this structure, a parasitic PNPTr is formed which is constituted of a P-type diffusion region (P-type semiconductor layer 202, P-type diffusion region 203 and high concentration P-type diffusion region 206; emitter) of the anode region, the N-type buried diffusion region 208 (base), and the P-type semiconductor substrate 201 (collector), The impurity concentration of the N-type buried diffusion region 208 is high. Further, under a forward bias, the N-type buried diffusion region 208 is connected, at the same potential as the anode potential, with the high concentration N-type sinker region 209. Owing to these facts, the operation of the parasitic PNPTr, i.e., the forward bias operation can be controlled and the substrate leakage current to the P-type semiconductor substrate 201 can be greatly improved under a forward bias.
Reference 1: Japanese National Phase PCT Laid-Open Publication No. 2009-520349 (U.S. Pat. No. 7,659,584 B2)
Reference 2: Japanese National Phase PCT Laid-Open Publication No. 2007-535812 (U.S. Pat. No. 7,095,092 B2)

### SUMMARY OF THE INVENTION

In the conventional high voltage diode 200 described in Reference 2, the characteristic structure includes the N-type buried diffusion region 208. Thus, it is difficult to bury the high concentration N-type buried diffusion region 208 into the deep part of the P-type semiconductor substrate 201 by high energy implantation. Basically, after epitaxial growth, it is necessary to form the high concentration N-type buried diffusion region 208 therein, which causes disadvantages in terms of manufacturing and cost.

In addition, since the electric potential of the N-type buried diffusion region 208 is set to be the same as the anode potential, the N-type sinker region 209 reaching the deep part of the P-type semiconductor substrate 201 is necessary. Furthermore, the reverse-conductivity-type P-type diffusion region 204 is necessary in between the N-type buried diffusion region 208 and the N-type diffusion region 207 in order to electrically separate the N-type buried diffusion region 208 from the cathode region (N-type diffusion region 207 and high concentration N-type diffusion region 205). Due to these facts, excessive diffusion regions, such as the N-type sinker region 209 and the P-type diffusion region 204, are necessary.

The present invention is intended to solve the conventional problems described above. It is an objective of the present invention to provide: a semiconductor apparatus, capable of efficiently suppressing a substrate leakage current during a forward bias operation and being formed at a low cost, without having a conventional epitaxial layer or a high concentration buried diffusion region; and a method for manufacturing the semiconductor apparatus.

A semiconductor apparatus formed on a first-conductivity-type semiconductor layer according to the present invention includes: a second-conductivity-type first diffusion region formed on the semiconductor layer; a first-conductivity-type second diffusion region formed in the first diffusion region; a second-conductivity-type first high concentration diffusion region and a first-conductivity-type second high concentration diffusion region formed in the second diffusion region; a second-conductivity-type third high concentration diffusion region, formed at a position separated by a given distance away from the second diffusion region, in the first diffusion region; and a gate electrode formed above and between the first high concentration diffusion region and the third high concentration diffusion region, with a gate insulation film interposed therebetween, where the gate electrode is formed overlapping the first high concentration diffusion region, and the gate electrode is electrically connected with the first high concentration diffusion region and the second high concentration diffusion region, at the same potential, thereby achieving the objective described above.

Preferably, in a semiconductor apparatus according to the present invention, the first high concentration diffusion region, the third high concentration diffusion region, and the gate electrode provided therebetween constitute a reverse bias MOSFET.

Still preferably, in a semiconductor apparatus according to the present invention, one end of the gate electrode is separated by a given distance from the third high concentration diffusion region.

Still preferably, in a semiconductor apparatus according to the present invention, the first high concentration diffusion region, the second high concentration diffusion region, and the gate electrode are connected with an anode electrode, and the third high concentration diffusion region is connected with a cathode electrode.

Still preferably, in a semiconductor apparatus according to the present invention, a second-conductivity-type third diffusion region is included in the second-conductivity-type first diffusion region, and the third high concentration diffusion region is included in the third diffusion region.

Still preferably, in a semiconductor apparatus according to the present invention, an insulation separation film is included in the second-conductivity-type first diffusion region, the insulation separation film formed between the first-conductivity-type second diffusion region and the third high concentration diffusion region.

Still preferably, in a semiconductor apparatus according to the present invention, a second-conductivity-type third diffusion region is included in the second-conductivity-type first diffusion region; the third high concentration diffusion region and the insulation separation film are included in the third diffusion region; and the insulation separation film is formed between the first-conductivity-type second diffusion region and the third high concentration diffusion region.

Still preferably, in a semiconductor apparatus according to the present invention, the second diffusion region and the third diffusion region are separated from each other by a given distance below the gate electrode.

Still preferably, in a semiconductor apparatus according to the present invention, the second diffusion region and the insulation separation film are separated from each other by a given distance below the gate electrode.

Still preferably, in a semiconductor apparatus according to the present invention, the insulation separation film is provided for a given length including a lower end of the gate electrode on the side closer to the third high concentration diffusion region.

Still preferably, in a semiconductor apparatus according to the present invention, a second-conductivity-type buried diffusion region formed by high energy implantation is included at a bottom of the first-conductivity-type second diffusion region.

Still preferably, in a semiconductor apparatus according to the present invention, the first-conductivity-type semiconductor layer is a first-conductivity-type semiconductor substrate.

Still preferably, in a semiconductor apparatus according to the present invention, the first conductivity type, semiconductor layer is a first conductivity type, diffusion region.

Still preferably, in a semiconductor apparatus according to the present invention, the semiconductor apparatus is a high voltage diode.

A method for manufacturing a semiconductor apparatus formed on a first-conductivity-type semiconductor layer according to the present invention includes: a step of forming a second-conductivity-type first diffusion region on the semiconductor layer; a step of forming a first-conductivity-type second diffusion region in the first diffusion region; a step of forming a second-conductivity-type first high concentration diffusion region and a first-conductivity-type second high concentration diffusion region in the second diffusion region, and a second-conductivity-type third high concentration diffusion region, at a position separated by a given distance away from the second diffusion region, in the first diffusion region; a step of forming a gate electrode above and between the first high concentration diffusion region and the third high concentration diffusion region, with a gate insulation film interposed therebetween, in such a manner that the gate electrode is formed overlapping the first high concentration diffusion region vertically; and

a step of electrically connecting the gate electrode with the first high concentration diffusion region and the second high concentration diffusion region, at the same potential, thereby achieving the objective described above.

Preferably, in a method for manufacturing a semiconductor apparatus according to the present invention, the step of forming a first-conductivity-type second diffusion region in the first diffusion region includes a step of forming a second-conductivity-type third diffusion region in the first diffusion region, separated by a given distance away from the second diffusion region; and the step of forming a second-conductivity-type third high concentration diffusion region, at a position separated by a given distance away from the second diffusion region, in the first diffusion region, forms the third high concentration diffusion region in the third diffusion region, in the first diffusion region.

Still preferably, in a method for manufacturing a semiconductor apparatus according to the present invention, the step of forming a first-conductivity-type second diffusion region in the first diffusion region includes a step of forming an insulation separation film in the first diffusion region, separated by a given distance away from the second diffusion region.

Still preferably, in a method for manufacturing a semiconductor apparatus according to the present invention: the step of forming a first-conductivity-type second diffusion region in the first diffusion region includes a step of forming a second-conductivity-type third high concentration diffusion region, separated by a given distance away from the second diffusion region, in the first diffusion region, and of forming an insulation separation film, separated by a given distance away from the second diffusion region, the third diffusion region; and the step of forming a second-conductivity-type third high concentration diffusion region, at a position separated by a given distance away from the second diffusion region, in the first diffusion region, forms the third high concentration diffusion region in the third diffusion region, in the first diffusion region.

Still preferably, in a method for manufacturing a semiconductor apparatus according to the invention, the step of forming a first-conductivity-type second diffusion region in the first diffusion region includes a step of forming a second-conductivity-type buried diffusion region, by high energy implantation, at a bottom of the second diffusion region.

The functions of the present invention having the structures described above will be described hereinafter.

In the semiconductor apparatus according to the present invention, the semiconductor apparatus includes: a second-conductivity-type first diffusion region formed on the semiconductor layer; a first-conductivity-type second diffusion region formed in the first diffusion region; a second-conductivity-type first high concentration diffusion region and a first-conductivity-type second high concentration diffusion region, formed in the second diffusion region; a second-conductivity-type third high concentration diffusion region, formed at a position separated from the second diffusion region, in the first diffusion region; and a gate electrode formed above and between the first high concentration diffusion region and the third high concentration diffusion region, with a gate insulation film interposed therebetween, where the gate electrode is formed overlapping the first high concentration diffusion region, and the gate electrode is electrically connected with the first high concentration diffusion region and the second high concentration diffusion region, at the same potential. In the method for manufacturing the semiconductor apparatus in such a case, the method includes: a step of forming a second-conductivity-type first diffusion region on the semiconductor layer; a step of forming a first-conductivity-type second diffusion region in the first diffusion region; a step of forming a second-conductivity-type first high concentration diffusion region and a first-conductivity-type second high concentration diffusion region, in the second diffusion region; a step of forming a second-conductivity-type third high concentration diffusion region, at a position separated from the second diffusion region in the first diffusion region; a step of forming a gate electrode above and between the first high concentration diffusion region and the third high concentration diffusion region, with a gate insulation film interposed therebetween, in such a manner that the gate electrode is formed overlapping the first high concentration diffusion region vertically; and a step of electrically connecting the gate electrode with the first high concentration diffusion region and the second high concentration diffusion region, at the same potential.

Accordingly, while the substrate leakage current does not change, the forward current increases owing to a reverse bias MOSFET, and an operation point can be lowered with respect to a desired forward current. This allows effective suppression and a large decrease in the substrate leakage current during the forward bias operation, and allows forming the structure of the present invention at a low cost, without having an epitaxial layer or a high concentration buried diffusion region as is done conventionally.

According to the present invention with the structure described above, the substrate leakage current can be effectively suppressed during the forward bias operation, without having an epitaxial layer or a high concentration buried diffusion region, thereby forming the present invention at a low cost.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view schematically illustrating an exemplary structure of an essential part of a high voltage diode, as a semiconductor apparatus according to Embodiment 1 of the present invention.

FIG. 2 is a diagram of an equivalent circuit of the high voltage diode in FIG. 1.

FIG. 3 is a longitudinal cross sectional view schematically illustrating an exemplary cross sectional structure of an essential part of a conventional high voltage diode without a reverse bias MOSFET.

FIG. 4 is a diagram of an equivalent circuit of the high voltage diode in FIG. 3.

FIG. 5 is a graph illustrating the relationships between an anode voltage (V_{A}) and a forward current I_{b} as well as between an anode voltage (V_{A}) and a substrate leakage current I_{c}, with regard to the cases with or without a reverse bias MOSFET.

FIG. 6 is a graph illustrating forward characteristics between a high voltage diode according to Embodiment 1 with a reverse bias MOSFET, and a conventional high voltage diode without a reverse bias MOSFET.

FIGS. 7(a) to 7(c) each are longitudinal cross sectional views describing each manufacturing step in a method for manufacturing the high voltage diode in FIG. 1.

FIG. 8 is a longitudinal cross sectional view schematically illustrating an exemplary structure of an essential part of a high voltage diode, as a semiconductor apparatus according to Embodiment 2 of the present invention.

FIGS. 9(a) to 9(c) each are longitudinal cross sectional views describing each manufacturing step in a method for manufacturing the high voltage diode in FIG. 8.

FIG. 10 is a longitudinal cross sectional view schematically illustrating an exemplary structure of an essential part of a high voltage diode, as a semiconductor apparatus according to Embodiment 3 of the present invention.

FIGS. 11(a) to 11(c) each are longitudinal cross sectional views describing each manufacturing step in a method for manufacturing the high voltage diode in FIG. 10.

FIG. 12 is a longitudinal cross sectional view schematically illustrating an exemplary structure of an essential part of a high voltage diode, as a semiconductor apparatus according to Embodiment 4 of the present invention.

FIGS. 13(a) to 13(c) each are longitudinal cross sectional views describing each manufacturing step in a method for manufacturing the high voltage diode in FIG. 12.

FIG. 14 is a longitudinal cross sectional view schematically illustrating an exemplary structure of an essential part of a high voltage diode, as a semiconductor apparatus according to Embodiment 5 of the present invention.

FIG. 15 is a graph illustrating the relationship between a forward current I_{b} and an anode voltage (V_{A}), as well as the relationship between a substrate leakage current I_{c} according to Embodiments 1 and 5 and the anode voltage (V_{A}).

FIGS. 16(a) to 16(c) each are longitudinal cross sectional views describing each manufacturing step in a method for manufacturing the high voltage diode in FIG. 14.

FIG. 17 is a longitudinal cross sectional view schematically illustrating an exemplary structure of an essential part of a high voltage diode, as a semiconductor apparatus according to Embodiment 6 of the present invention.

FIG. 18(a) is a longitudinal cross sectional view schematically illustrating an exemplary cross sectional structure of an essential part of a conventional high voltage diode disclosed in Reference 1. FIG. 18(b) is a diagram describing current paths I1 and I2 as well as a substrate leakage current, under a forward bias in the longitudinal cross sectional view of FIG. 18(a).

FIG. 19 is a longitudinal cross sectional view schematically illustrating a sectional structure of an essential part of a conventional high voltage diode disclosed in Reference 2.

1 P-type semiconductor substrate
1A P-type diffusion region (P well layer)
2 N-type diffusion region
3 P-type diffusion region
4 high concentration N-type diffusion region
5 high concentration N-type diffusion region
6 high concentration P-type diffusion region
7 gate electrode
7A trench gate
8, 8A N-type diffusion region
9 insulation separation film
10 N-type buried diffusion region
11 N-type semiconductor substrate
21 to 26 high voltage diode
I_{b} forward current
I_{bp} base current
Iₑₙ emitter current
I_{MOS} current of a reverse bias MOSFET (Q1)
Vth threshold voltage of a reverse bias MOSFET
I_{c} substrate leakage current
V_{A1} anode voltage when there is a reverse bias MOSFET
V_{A2} anode voltage when there is not a reverse bias MOSFET
I_{c1} substrate leakage current when there is a reverse bias MOSFET
I_{c2} substrate leakage current when there is not a reverse bias MOSFET
L length
VF, V_{F1}, V_{F2} forward voltage

### DESCRIPTION OF THE PREFERRED EMBODIMENTS

Hereinafter, Embodiments 1 to 6 will be described where the semiconductor apparatus according to the present invention and a method for manufacturing the semiconductor apparatus are applied to a high voltage diode and a method for manufacturing the high voltage diode, with reference to the accompanying figures. Note that the thickness, length and the like of constituent elements in each of the figures are not limited to those of the illustrated structures in terms of the production of the figures.

### Embodiment 1

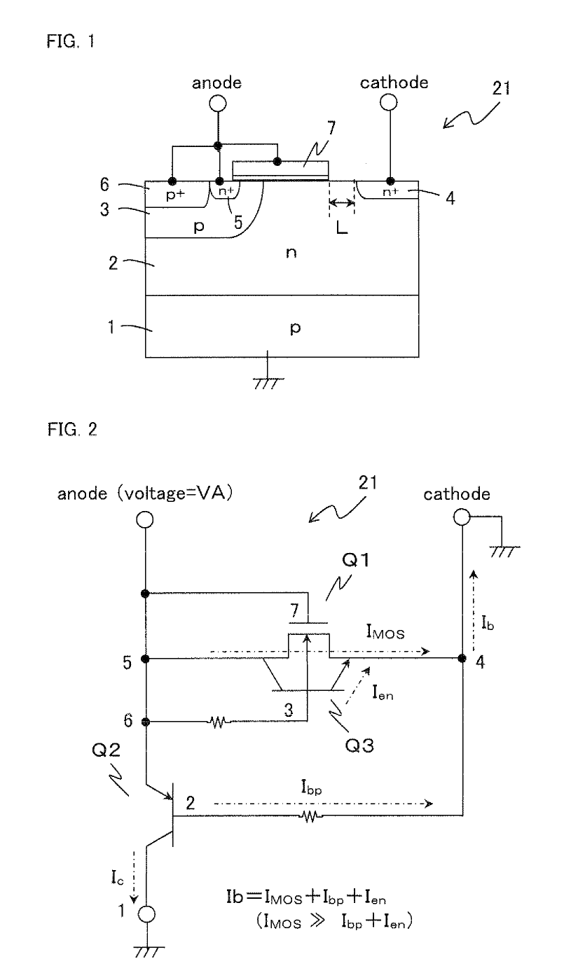

FIG. 1 is a longitudinal cross sectional view schematically illustrating an exemplary structure of an essential part of a high voltage diode, as a semiconductor apparatus according to Embodiment 1 of the present invention.

In FIG. 1, a high voltage diode 21, as a semiconductor apparatus according to Embodiment 1, is a semiconductor apparatus formed on a P-type semiconductor substrate 1. An N-type diffusion region 2 is included in the P-type semiconductor substrate 1. A P-type diffusion region 3 and a high concentration N-type diffusion region 4 are included in the N-type diffusion region 2, the high concentration N-type diffusion region 4 being formed at a position horizontally separated from the P-type diffusion region 3.

In addition, a high concentration N-type diffusion region 5 and a high concentration P-type diffusion region 6 are formed in the P-type diffusion region 3. Agate electrode 7 is formed above the N-type diffusion region 2 and the P-type diffusion region 3, and between the high concentration N-type diffusion region 5 and the high concentration N-type diffusion region 4, with a gate oxide film interposed therebetween. One of the end portions of the gate electrode 7 is formed overlapping the high concentration N-type diffusion region 5.

Further, a cathode electrode is formed above the high concentration N-type diffusion region 4, and the cathode electrode is electrically connected with the high concentration N-type diffusion region 4. An anode electrode is formed above the high concentration N-type diffusion region 5 and the high concentration P-type diffusion region 6. By the anode electrode, the high concentration N-type diffusion region 5, the high concentration P-type diffusion region 6 and the gate electrode 7 are electrically connected with one another at the same potential.

The high voltage diode 21, as a semiconductor apparatus according to Embodiment 1, is structured as described above. The high voltage diode 21 includes a reverse bias MOSFET built therein in parallel with a PN diode during the forward bias operation. In this regard, the structure of the high voltage diode 21 is totally different from that of a conventional high voltage diode without a reverse bias MOSFET

The matter above described will be described in detail with reference to accompanying figures.

FIG. 2 is a diagram of an equivalent circuit of the high voltage diode in FIG. 1.

As illustrated in FIG. 2, the high voltage diode 21 according to Embodiment 1 includes a characteristic structure of having a reverse bias MOSFET (Q1), which is constituted of a high concentration N-type diffusion region 5 (drain), an N-type diffusion region 2 (source), a P-type diffusion region 3 (body), and a gate electrode 7, during the forward bias operation of the diode.

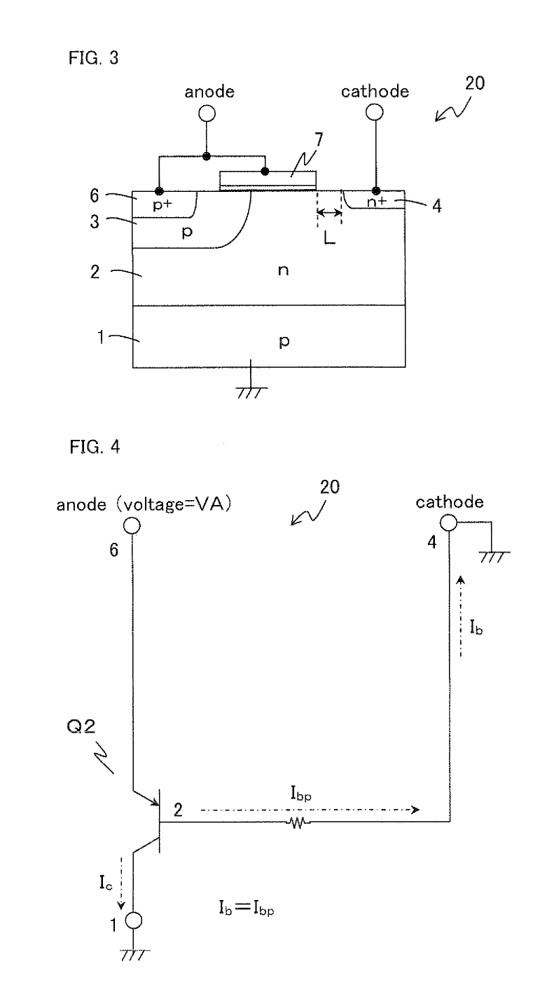

For a comparison with the high voltage diode 21 according to Embodiment 1 with a reverse bias MOSFET, FIG. 3 illustrates a case of a high voltage diode without a reverse bias MOSFET, i.e., a case of a high voltage diode 20 obtained by removing the high concentration N-type diffusion region 5 from the high voltage diode illustrated in FIG. 1. In addition, FIG. 4 illustrates an equivalent circuit of the high voltage diode 20 in FIG. 3.

As illustrated in FIG. 4, for the high voltage diode 20 without a reverse bias MOSFET in FIG. 3, when the high voltage diode 20 is operated under a forward bias, a forward current I_{b} matches a base current I_{bp} of a parasitic PNPTr (Q2), satisfying the relationship of I_{b}=I_{bp}.

In the meantime, as illustrated in FIG. 2, when the high voltage diode 21 with a reverse bias MOSFET in FIG. 1 is operated under a forward bias, the forward current Ib is the sum of a base current I_{bp} of the parasitic PNPTr (Q2), an emitter current Iₑₙ of a parasitic NPNTr (Q3) and a current I_{MOS} of a reverse bias MOSFET (Q1), satisfying the relationship of

I_{b}=I_{MOS}+I_{bp}+Iₑₙ (formula 1).

Hereinafter, the current I_{MOS} of the reverse bias MOSFET will be further described in detail.

When the high voltage diode 21 in FIG. 2 is operated under a forward bias, the anode potential is higher than the cathode potential (GND potential). Thus, the P-type diffusion region 3, corresponding to a body, is higher than the N-type diffusion region 2, corresponding to a source. Due to a substrate bias effect, a threshold voltage (denoted to as Vth, hereinafter) of the reverse bias MOSFET becomes extremely small. As a result, an inversion layer is formed by the gate electrode 7 connected with the anode electrode at the same potential, and a current flows to the reverse bias MOSFET (Q1).

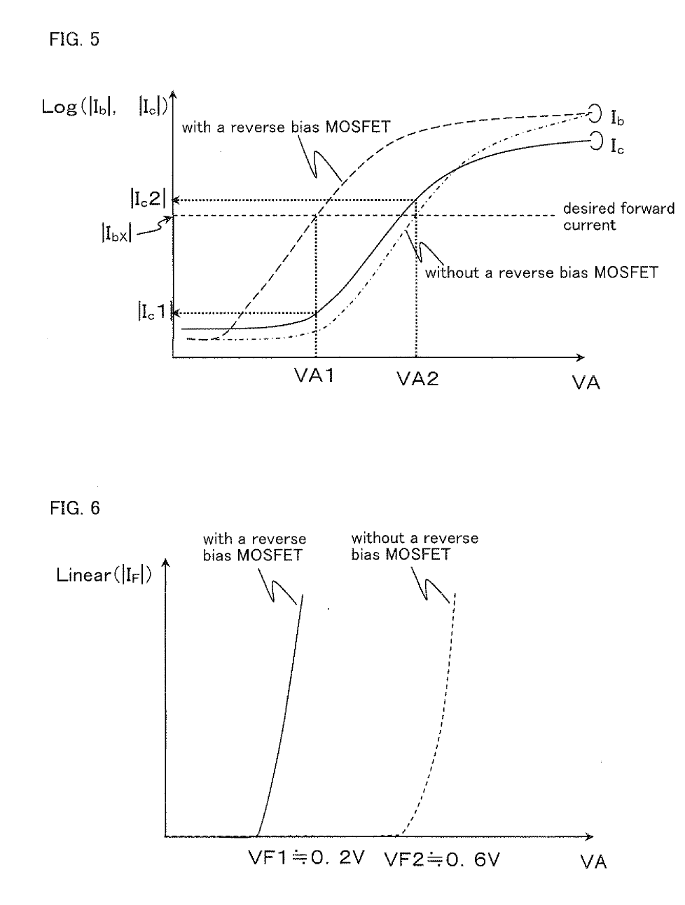

FIG. 5 illustrates a Gummel plot of the high voltage diode 21 with a reverse bias MOSFET and a high voltage diode without a reverse bias MOSFET. In FIG. 5, the axis of abscissas indicates a value of an anode voltage (V_{A}), and the axis of ordinates indicates a forward current I_{b} and a substrate leakage current I_{c} to the P-type semiconductor substrate 1.

As illustrated in FIG. 5, there is no difference in the substrate leakage current I_{c} to the P-type semiconductor substrate 1 in both the case with a reverse bias MOSFET and the case without a reverse bias MOSFET. With regards to the forward current I_{b}, however, the forward current I_{b} begins to increase from a region with a low anode voltage in the case with a reverse bias MOSFET, as compared to the case without a reverse bias MOSFET. This is due to the threshold voltage Vth being reduced by the substrate bias effect, indicating that an inversion layer is formed in the reverse bias MOSFET (Q1) and the current I_{MOS} is increasing exponentially.

Therefore, during the forward bias operation, the current I_{MOS} expressed in the formula (I) becomes extremely larger than the currents I_{bp} or Iₑₙ (I_{MOS}>>I_{bp}+Iₑₙ). Thus, it can be understood that the forward current I_{b} greatly increases in the case with a reverse bias MOSFET, compared to the case without a reverse bias MOSFET.

As a result, as illustrated in FIG. 5, for example in the circuit, if a desired forward current is defined to be I_{bx}, then the anode voltage is V_{A1} when a reverse bias MOSFET is included, and the anode voltage is V_{A2} when a reverse bias MOSFET is not included. Simultaneously, it can be understood that, when a reverse bias MOSFET is included, the substrate leakage current to the P-type semiconductor substrate 1 is I_{c1}, and I_{c1} is greatly reduced when compared to the substrate leakage current I_{c2} in the case without a reverse bias MOSFET.

Therefore, as previously stated, in the high voltage diode 21 according to Embodiment 1, the threshold voltage Vth of the built-in reverse bias MOSFET is greatly reduced by the substrate bias effect during the diode forward bias operation. As a result, the forward current I_{b} greatly increases by the on-mode of the reverse bias MOSFET, and the anode voltage, corresponding to the desired forward current I_{b}, substantially reduces, thus greatly reducing the substrate leakage current to the P-type semiconductor substrate 1.

On the other hand, when a reverse bias is applied to the high voltage diode 21 in FIG. 1, a positive voltage with respect to the anode electrode is applied to the cathode electrode. Thus, when the length of L (≧0 μm) in FIG. 1 is adjusted and/or the profile of the N-type diffusion region 2 is adjusted, resistance to high voltage can be achieved and a current under a reverse bias can be favorably stopped.

FIG. 6 is a graph illustrating forward characteristics between a high voltage diode 21 according to Embodiment 1 with a reverse bias MOSFET, and a conventional high voltage diode without a reverse bias MOSFET.

As illustrated in FIG. 6, while the forward voltage V_{F2}≈0.6V in the case with a conventional high voltage diode without a reverse bias MOSFET, the forward voltage V_{F1}≈0.2V in the base with the high voltage diode 21 according to Embodiment 1 with a reverse bias MOSFET. This is a forward voltage VF on par with a Schottky diode and allows a large reduction in the forward voltage VF. A reverse recovery time (a time until an excess current, which flows upon switching from a forward bias to a reverse bias, diminishes) can be further mentioned as one of major features of a high voltage diode. In the case with the high voltage diode 21 with a reverse bias MOSFET, most of the forward current is a channel current of a reverse MOSFET, making it possible to greatly decrease the reverse recovery time.

As described above, in the high voltage diode 21 according to Embodiment 1, the substrate leakage current during the forward operation can be effectively suppressed without having an epitaxial layer or a high concentration buried diffusion region, and further allows the decrease in the forward voltage (W) and the decrease in the reverse recovery time.

Next, a method for manufacturing a high voltage diode 21 with the structure described above will be described.

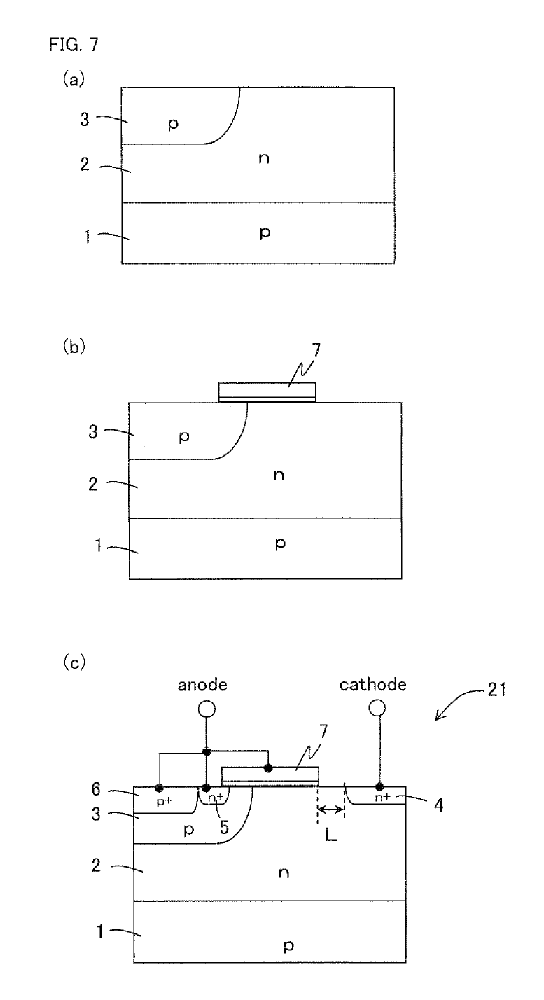

FIGS. 7(a) to 7(c) each are longitudinal cross sectional views of an essential part, for describing each manufacturing step of a method for manufacturing a high voltage diode 21 in FIG. 1.

As illustrated in FIG. 7(a), N-type impurities are implanted into a P-type semiconductor substrate 1, and an N-type diffusion region 2 is formed at a desired depth by thermal diffusion processing with high temperature drive-in. Phosphorus, for example, is used as the N-type impurities. The implantation energy is, for example, 2 MeV or more, and the dose is 1.0×10¹³ cm⁻² or less. For example, for the region into which the N-type impurities are implanted, such an impurity implantation region is defined by using a thick resist for coping with high energy implantation and by patterning such that an opening is made for the region into which impurities are implanted by a photoetching technique or the like. Further, P-type impurities, such as boron, are implanted into the N-type diffusion region 2 to form a P-type diffusion region 3 in a given region.

Next, as illustrated in FIG. 7(b), a gate insulation film is formed on a surface region of the N-type diffusion region 2 and a P-type diffusion region 3. On the gate insulation film, a gate electrode 7 is formed in such a manner that the gate electrode 7 stretches over the N-type diffusion region 2 from a part of the P-type diffusion region 3. For the material of the gate electrode 7, a polysilicon film, in which phosphorus is doped, for example, is formed by CVD. A resist is patterned on the polysilicon film by a photoetching technique, and subsequently, the polysilicon film is processed into a given shape by a dry etching technique or the like to form the gate electrode 7.

Subsequently, as illustrated in FIG. 7(c), a high concentration N-type diffusion region 4 and a high concentration N-type diffusion region 5 are formed in a given region by N-type impurity implantation of phosphorus or arsenic, for example. Also, by P-type impurity implantation of boron, for example, a high concentration P-type diffusion region 6 is formed adjacent to the high concentration N-type diffusion region 5 in the P-type diffusion region 3.

At this stage, the high concentration N-type diffusion region 5 is formed in a self-aligned manner with respect to the gate electrode 7, and thermal processing is provided thereafter. Therefore, the gate electrode 7 is always formed overlapping the high concentration N-type diffusion region 5. With regard to the high concentration N-type diffusion region 4, a separate distance L (≧0 μm) between the high concentration N-type diffusion region 4 and the gate electrode 7 is set in accordance with a desired resisting voltage. In the case of L>0 μm, the separate distance L is defined by the resist mask used for implanting N-type impurities into the high concentration N-type diffusion region 4.

Further, although not illustrated in FIG. 7(c), an oxide film is formed by atmospheric pressure CVD, for example, on the substrate surface thereafter, and the difference in levels on the surface is reduced by reflow. Subsequently, contact etching is performed on the previously-mentioned oxide film above the gate electrode 7, the high concentration N-type diffusion region 5, the high concentration N-type diffusion region 4 and the high concentration P-type diffusion region 6, to form an opening. Further, an aluminum film is formed by sputtering, for example, and subsequently, the aluminum film is patterned into a given shape by photoetching and dry etching to form a metal electrode.

At this stage, the high concentration N-type diffusion region 5, high concentration P-type diffusion region 6 and the gate electrode 7 are electrically connected with one another by the metal electrode at the same potential.

As described above, the high voltage diode 21 according to Embodiment 1 with a reverse bias MOSFET (Q1) is formed on the P-type semiconductor substrate 1.

In summary, the method for manufacturing the high voltage diode 21 according to Embodiment 1 includes: a step of forming the N-type diffusion region 2 on the P-type semiconductor substrate 1; a step of forming the P-type diffusion region 3 in the N-type diffusion region 2; a step of forming the high concentration N-type diffusion region 5, the high concentration P-type diffusion region 6 in the P-type diffusion region 3, and the high concentration N-type diffusion region 4 at a position separated by a given distance away from the P-type diffusion region 3 in the N-type diffusion region 2; a step of forming the gate electrode 7 above and between the high concentration N-type diffusion region 5 and the high concentration N-type diffusion region 4, with a gate insulation film interposed therebetween, in such a manner that the gate electrode 7 is formed overlapping the high concentration N-type diffusion region 5 vertically; and a step of electrically connecting the gate electrode 7 with the high concentration N-type diffusion region 5 and the high concentration P-type diffusion region 6, at the same potential.

### Embodiment 2

In Embodiment 2, a case will be described where a second-conductivity-type third diffusion region (N-type diffusion region 8) is included in a second-conductivity-type first diffusion region (N-type diffusion region 2), and a third high concentration diffusion region (high concentration N-type diffusion region 4) is included in the third diffusion region (N-type diffusion region 8), in addition to the structure in Embodiment 1.

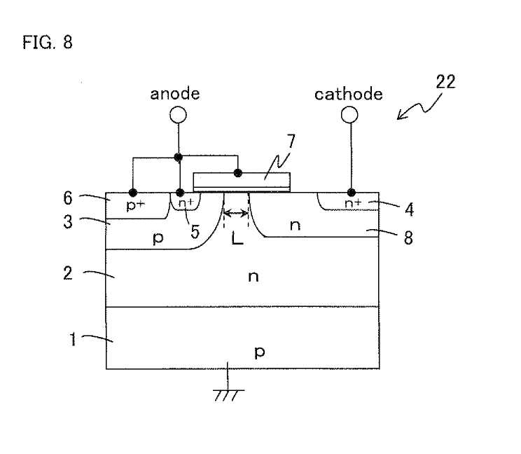

FIG. 8 is a longitudinal cross sectional view schematically illustrating an exemplary structure of an essential part of a high voltage diode, as a semiconductor apparatus according to Embodiment 2 of the present invention.

In FIG. 8, a high voltage diode 22 according to Embodiment 2 includes a characteristic structure of including an N-type diffusion region 8, which is formed in an N-type diffusion region 2 and includes a high concentration N-type diffusion region 4 therein, in order to reduce an on-resistance of a reverse bias MOSFET (Q1) as compared to the high voltage diode 21 according to Embodiment 1. The high concentration N-type diffusion region 4 is formed in the N-type diffusion region 8.

According to Embodiment 2, the on-resistance of the reverse bias MOSFET (Q1) is decreased during a forward bias operation, compared to the case of Embodiment 1. This allows a decrease in the forward voltage particularly in a high current region, with respect to a desired forward current.

In addition, under a reverse bias, the adjustment to a separate distance L (≧0 μm) between a P-type diffusion region 3 and a N-type diffusion region 8 and/or a profile of the N-type diffusion region 8 makes it possible to achieve resistance of high voltage and to favorably stop a current under the reverse bias operation.

Further, as previously mentioned, it is apparent that a decrease in the forward voltage (VF) and a decrease in the reverse recovery time are also feasible in Embodiment 2.

Next, a method for manufacturing a high voltage diode 22 with the structure described above will be described.

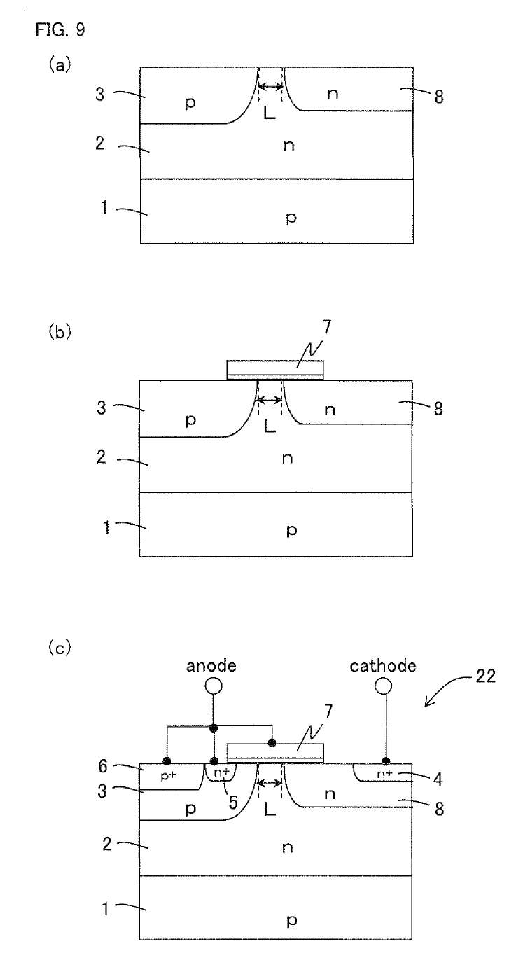

FIGS. 9(a) to 9(c) each are a longitudinal cross sectional view of an essential part, for describing each manufacturing step in a method for manufacturing a high voltage diode 22 in FIG. 8.

As illustrated in FIG. 9(a), in a comparison with the manufacturing method according to Embodiment 1, N-type impurities are first implanted into a P-type semiconductor substrate 1, and an N-type diffusion region 2 is formed at a desired depth by thermal diffusion processing with high temperature drive-in.

Next, a P-type diffusion region 3 is formed in a given region in the N-type diffusion region 2, and subsequently, an N-type diffusion region 8 is formed in a given region in the N-type diffusion region 2. For the implantation of N-type impurities into the N-type diffusion region 8, phosphorus, for example, is used, and the implantation dose is 1.0×10¹² cm⁻² or more.

A separate distance L (≧0 μm) between the P-type diffusion region 3 and the N-type diffusion region 8 is set in accordance with a desired amount of voltage resistance. The separate distance L is defined by the patterning of a resist mask upon forming the N-type diffusion region 8.

Subsequently, as illustrated in FIG. 9(b), a gate insulation film is formed on the surface of the N-type diffusion region 2, the P-type diffusion region 3 and the N-type diffusion region 8. On the gate insulation film, a gate electrode 7 is formed in such a manner that the gate electrode 7 stretches over a part of the N-type diffusion region 8 from a part of the P-type diffusion region 3 via the N-type diffusion region 2.

The subsequent steps are illustrated in FIG. 9(c); however, the subsequent steps are performed under the same conditions as the case of the manufacturing method according to Embodiment 1 in FIG. 7(c). Thus, the explanation will be omitted herein.

As described above, the high voltage diode 22 according to Embodiment 2 with the reverse bias MOSFET (Q1) is formed on the P-type semiconductor substrate 1.

In summary, the method for manufacturing the high voltage diode 22 according to Embodiment 2 includes: a step of forming the N-type diffusion region 2 on the P-type semiconductor substrate 1; a step of forming the P-type diffusion region 3 in the N-type diffusion region 2 and of forming the N-type diffusion region 8 with a given distance away from the P-type diffusion region 3, in the N-type diffusion region 2; a step of forming the high concentration N-type diffusion region 5 and the high concentration P-type diffusion region 6 in the P-type diffusion region 3, and in the N-type diffusion region 8, the high concentration N-type diffusion region 4 at a position separated by a given distance away from the P-type diffusion region 3 in the N-type diffusion region 2; a step of forming the gate electrode 7 above and between the high concentration N-type diffusion region 5 and the high concentration N-type diffusion region 4, with a gate insulation film interposed therebetween, in such a manner that the gate electrode 7 is formed overlapping the high concentration N-type diffusion region 5 vertically; and a step of electrically connecting the gate electrode 7 with the high concentration N-type diffusion region 5 and the high concentration P-type diffusion region 6, at the same potential.

### Embodiment 3

In Embodiment 3, a case will be described where an insulation separation film is included in addition to the structure in Embodiment 1, the insulation separation film being formed between a first-conductivity-type second diffusion region (P-type diffusion region 3) and a third high concentration diffusion region (high concentration N-type diffusion region 4) in a second-conductivity-type first diffusion region (N-type diffusion region 2),

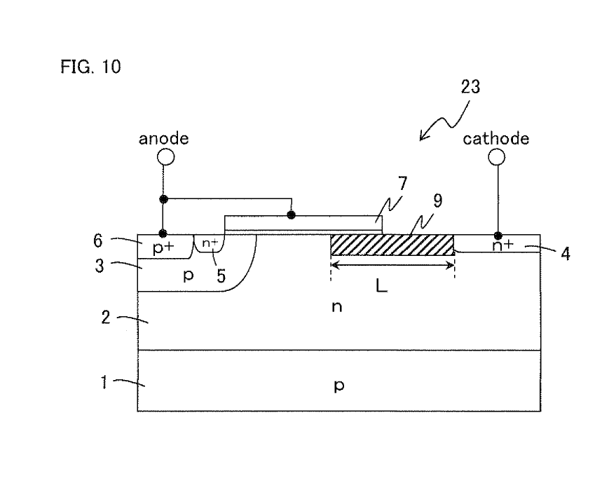

FIG. 10 is a longitudinal cross sectional view schematically illustrating an exemplary structure of an essential part of a high voltage diode, as a semiconductor apparatus according to Embodiment 3 of the present invention.

In FIG. 10, a high voltage diode 23 according to Embodiment 3 includes a characteristic structure of having an insulation separation film 9 formed between a P-type diffusion region 3 and a high concentration N-type diffusion region 4 in an N-type diffusion region 2, as compared with the high voltage diode 21 according to Embodiment 1.

According to Embodiment 3, the provision of the insulation separation film 9 allows for greatly reducing an electric field during a reverse bias, as compared to the case of Embodiment 1, making it possible to resist high voltage even more. In Embodiment 1, since an electric field is concentrated at a gate edge (defined to be a region A) on the cathode side of the gate electrode 7 under a reverse bias, there is a limit to the resisting of high voltage. However, by the insulation separation film 9 illustrated in FIG. 10, the electric field in the region A (one end of the gate electrode 7) can be greatly reduced, making it possible to resist high voltage even more.

Therefore, the adjustment to a length L of the insulation separation film 9 illustrated in FIG. 10 makes it possible to resist high voltage even more and to favorably stop current under the reverse bias operation.

Further, as previously mentioned, it is apparent that a decrease in the forward voltage (VF) and a decrease in the reverse recovery time are also feasible in Embodiment 3.

Next, a method for manufacturing a high voltage diode 23 with the structure described above will be described.

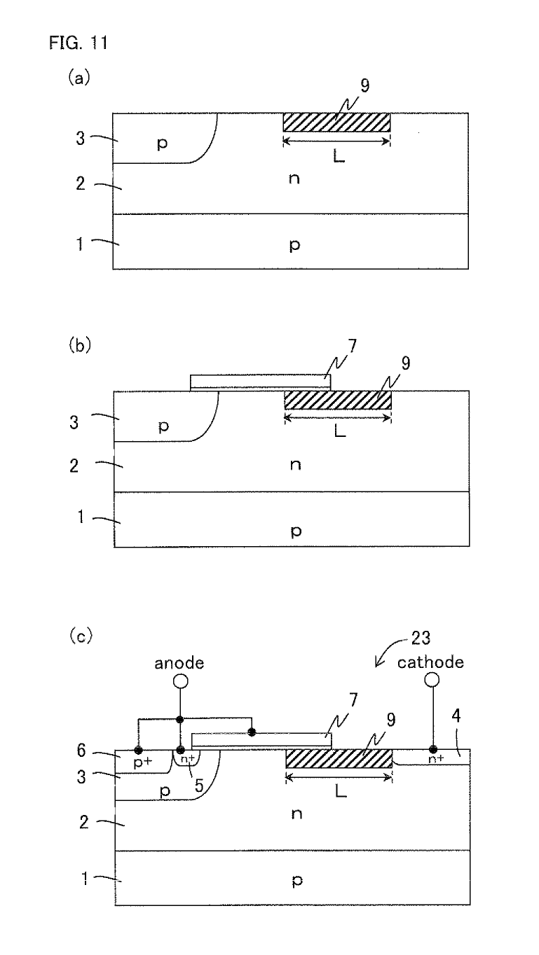

FIGS. 11(a) to 11(c) each are longitudinal cross sectional views of an essential part, for describing each manufacturing step in a method for manufacturing the high voltage diode 23 in FIG. 10.

As illustrated in FIG. 11(a), N-type impurities are first implanted into a P-type semiconductor substrate 1, and an N-type diffusion region 2 is formed at a desired depth by thermal diffusion processing with high temperature drive-in. Phosphorus, for example, is used as the N-type impurities. The implantation energy is, for example, 2 MeV or more, and the dose is 1.0×10¹³ cm⁻² or less. In addition, the region into which the N-type impurities are implanted is defined by using a thick resist for coping with high energy implantation and by patterning such that an opening is made for the region into which impurities are implanted by a photoetching technique or the like.

Further, an insulation separation film 9 is formed on a part (given region) of the surface of the N-type diffusion region 2. A P-type diffusion region 3 is formed by impurity implantation of a P-type impurity, such as boron at a region separated by a given distance away from the insulation separation film 9. The length (L in the figure) of the insulation separation film 9 in FIG. 11(a) is set in accordance with a desired resisting voltage (where higher voltage resistance is possible when the length is longer). For example, when the aim is to resist high voltage of 60 V or more, the length L of the insulation separation film 9 is set to be 1.5 μm or more. Note that the insulation separation film 9 may also be formed by LOCOS (Local Oxidation of Silicon) or STI (Shallow Trench Isolation).

Next, as illustrated in FIG. 11(b), a gate insulation film is formed on a surface region of the N-type diffusion region 2, the P-type diffusion region 3 and the insulation separation film 9. On the gate insulation film, a gate electrode 7 is formed in such a manner that the gate electrode 7 stretches over apart of the insulation separation film 9 from a part of the P-type diffusion region 3 via the N-type diffusion region 2. For the material of the gate electrode 7, a polysilicon film in which phosphorus is doped, for example, is formed by CVD. A resist is patterned on the polysilicon film by a photoetching technique, and subsequently, the polysilicon film is processed into a given shape by a dry etching technique or the like to form the gate electrode 7.

Subsequently, as illustrated in FIG. 11(c), a high concentration N-type diffusion region 5 and a high concentration N-type diffusion region 4 are formed by impurity implantation of phosphorus or arsenic, for example. Also, by impurity implantation of boron, for example, a high concentration P-type diffusion region 6 is formed.

At this stage, the high concentration N-type diffusion region 5 is formed in a self-aligned manner with respect to the gate electrode 7, and thermal processing is also provided. Therefore, the gate electrode 7 is always formed overlapping the high concentration N-type diffusion region 5. The high concentration N-type diffusion region 4 is formed in a self-aligned manner with respect to the insulation separation film 9.

Further, although not illustrated in the figure, an oxide film is formed on the surface by atmospheric pressure CVD, for example, and the difference in levels on the surface is reduced by reflow. Subsequently, contact etching is performed on the previously-mentioned oxide film above the gate electrode 7, the high concentration N-type diffusion region 5, the high concentration P-type diffusion region 6 and the high concentration N-type diffusion region 4, to form an opening. Further, an aluminum film is formed by sputtering, for example, and subsequently the aluminum film is patterned by photoetching and dry etching to form a metal electrode.

At this stage, the high concentration N-type diffusion region 5, the high concentration P-type diffusion region 6 and the gate electrode 7 are electrically connected with one another by the metal electrode at the same potential

As described above, the high voltage diode 23 according to Embodiment 3 with a reverse bias MOSFET (Q1) is formed on the P-type semiconductor substrate 1.

In summary, the method for manufacturing the high voltage diode 23 according to Embodiment 3 includes: a step of forming the N-type diffusion region 2 in the P-type semiconductor substrate 1; a step of forming the P-type diffusion region 3, and of forming the insulation separation film 9 with a given distance away from the P-type diffusion region 3 in the N-type diffusion region 2; a step of forming the high concentration N-type diffusion region 5 and the high concentration P-type diffusion region 6 in the P-type diffusion region 3, and the high concentration N-type diffusion region 4 at a position separated by a given distance away from the P-type diffusion region 3, in the N-type diffusion region 2; a step of forming the gate electrode 7 above and between the high concentration N-type diffusion region 5 and the high concentration N-type diffusion region 4, with a gate insulation film interposed therebetween, in such a manner that the gate electrode 7 is formed overlapping the high concentration N-type diffusion region 5 vertically; and a step of electrically connecting the gate electrode 7 with the high concentration N-type diffusion region 5 and the high concentration P-type diffusion region 6, at the same potential.

### Embodiment 4

In Embodiment 4, a case will be described where in addition to the structure in Embodiment 1, a first-conductivity-type second diffusion region (P-type diffusion region 3) and a second-conductivity-type third high concentration diffusion region (N-type diffusion region 8A) are included in a second-conductivity-type first diffusion region (N-type diffusion region 2); a third high concentration diffusion region (high concentration N-type diffusion region 4) is included in the third diffusion region (N-type diffusion region 8A); and an insulation separation film 9 formed between the first-conductivity-type second diffusion region (P-type diffusion region 3) and the third high concentration diffusion region (high concentration N-type diffusion region 4) is included.

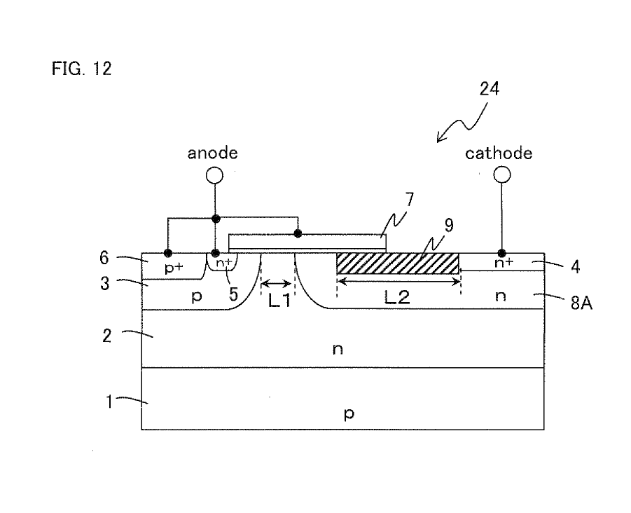

FIG. 12 is a longitudinal cross sectional view schematically illustrating an exemplary structure of an essential part of a high voltage diode, as a semiconductor apparatus according to Embodiment 4 of the present invention.

In FIG. 12, a high voltage diode 24 according to Embodiment 4 is formed such that the P-type diffusion region 3 and the N-type diffusion region 8A are separated from each other by a given distance L1 in the N-type diffusion region 2 below the gate electrode 7, as compared with the high voltage diode 21 according to Embodiment 1. In addition, the high voltage diode 24 includes a characteristic structure of having the insulation separation film 9 and the high concentration N-type diffusion region 4 formed in parallel with each other in the N-type diffusion region 8A, and having the insulation separation film 9 with a given length L2 in the N-type diffusion region 8A between the P-type diffusion region 3 and the high concentration N-type diffusion region 4. In summary, Embodiment 4 is a case where the N-type diffusion region 8 in Embodiment 2 is combined with the insulation separation film 9 in Embodiment 3.

According to Embodiment 4 as described above, compared with the case of Embodiment 1, a concentrated electric field at one end on the cathode side of the gate electrode 7 can be greatly reduced under a reverse bias, as the effect of Embodiment 3, thereby resisting higher voltage. In addition, according to Embodiment 4, an on-resistance of a reverse MOSFET is decreased under a forward bias, as the effect of Embodiment 2, thereby decreasing a forward voltage particularly in a high current region with respect to a desired forward current.

In addition, under a reverse bias, the adjustment to a separate distance L1 (≧0 μm) between the P-type diffusion region 3 and the N-type diffusion region 8A, the length L2 of the insulation separation film 9 and the profile of the N-type diffusion region 8A makes it possible to resist high voltage even more and favorably stop a current under the reverse bias operation.

Further, as previously mentioned, it is apparent that a decrease in the forward voltage (VF) and a decrease in the reverse recovery time are also feasible in Embodiment 4.

Next, a method for manufacturing a high voltage diode 24 with the structure described above will be described.

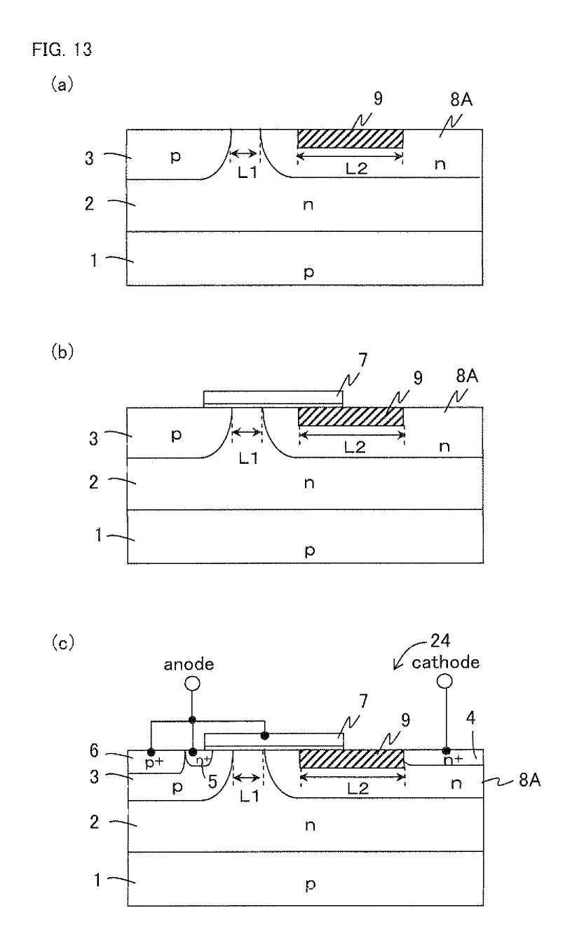

FIGS. 13(a) to 13(c) each are longitudinal cross sectional views of an essential part, for describing each manufacturing step in a method for manufacturing the high voltage diode 24 in FIG. 12.

As illustrated in FIG. 13(a), an N-type diffusion region BA is first formed in an N-type diffusion region 2. Phosphorus, for example, is used for the impurity implantation into the N-type diffusion region BA. The implantation energy is, for example, 200 KeV or more, and the dose is 1.0×10¹² cm⁻² or more.

Further, an insulation separation film 9 is formed in a part (given region) of the surface of the N-type diffusion region 8A. A P-type diffusion region 3 is further formed at a given region in the N-type diffusion region 2 separated by a given distance L1 away from the N-type diffusion region 8A, by impurity implantation of a P-type impurity, such as boron. The length (L2 in the figure) of the insulation separation film 9 is set in accordance with a desired resisting voltage. Note that the insulation separation film 9 may also be formed by LOCOS (Local Oxidation of Silicon) or STI (Shallow Trench Isolation).

Next, as illustrated in FIG. 13(b), a gate insulation film is formed on each surface region of the N-type diffusion fusion region 2, the P-type diffusion region 3, the N-type diffusion region 8A and the insulation separation film 9. On the gate insulation film, a gate electrode 7 is formed in such a manner that the gate electrode 7 stretches over a part of the insulation separation film 9 from a part of the P-type diffusion region 3 via the N-type diffusion region 2 and the N-type diffusion region 8A. For the material of the gate electrode 7, a polysilicon film in which phosphorus is doped, for example, is formed by CVD. A resist is patterned on the polysilicon film by a photoetching technique, and subsequently, the polysilicon film is processed into a given shape by a dry etching technique or the like to form the gate electrode 7.

In this case, a separate distance L1 (≧0 μm) between the P-type diffusion region 3 and the N-type diffusion region 8A, and the length L2 of the insulation separation film 9 are set in accordance with a desired resisting voltage. The separate distance L1, however, is defined by the resist mask upon implanting impurities into the N-type diffusion region 8A.

At this stage, the high concentration N-type diffusion region 5 is formed in a self-aligned manner with respect to the gate electrode 7, and thermal processing is also provided. Therefore, the gate electrode 7 is always formed overlapping the high concentration N-type diffusion region 5. The high concentration N-type diffusion region 4 is formed in a self-aligned manner with respect to the insulation separation film 9, and therefore, the high concentration N-type diffusion region 4 is provided adjacent to the insulation separation film 9.

Next, an oxide film is formed on the surface by atmospheric pressure CVD, for example, and the difference in levels on the surface is reduced by reflow. Subsequently, contact etching is performed on the previously-mentioned oxide film above the gate electrode 7, the high concentration N-type diffusion region 5, and a high concentration P-type diffusion region 6, and above the high concentration N-type diffusion region 4, to form an opening. Further, an aluminum film is formed by sputtering, for example, and subsequently the aluminum film is patterned by photoetching and dry etching to form a metal electrode.

At this stage, the high concentration N-type diffusion region 5, the high concentration P-type diffusion region 6 and the gate electrode 7 are electrically connected with one another by the metal electrode at the same potential.

As described above, the high voltage diode 24 according to Embodiment 4 with a reverse bias MOSFET (Q1) is formed in the P-type semiconductor substrate 1.

In summary, the method for manufacturing the high voltage diode 24 according to Embodiment 4 includes: a step of forming the N-type diffusion region 2 in the P-type semiconductor substrate 1; a step of forming the P-type diffusion region 3, of forming the N-type diffusion region 8A with a given distance away from the P-type diffusion region 3 in the N-type diffusion region 2, and of forming the insulation separation film 9 with a given distance away from the P-type diffusion region 3 in the N-type diffusion region 8A; a step of forming the high concentration N-type diffusion region 5 and the high concentration P-type diffusion region 6 in the P-type diffusion region 3, and the high concentration N-type diffusion region 4 at a position separated by a given distance away from the P-type diffusion region 3 in the N-type diffusion region 2; a step of forming the gate electrode 7 above and between the high concentration N-type diffusion region 5 and the high concentration N-type diffusion region 4, with a gate insulation film interposed therebetween, in such a manner that the gate electrode 7 is formed overlapping the high concentration N-type diffusion region 5 vertically; and a step of electrically connecting the gate electrode 7 with the high concentration N-type diffusion region 5 and the high concentration P-type diffusion region 6, at the same potential.

### Embodiment 5

In Embodiment 5, a case will be described where an N-type buried diffusion region (N-type buried diffusion region 10 to be described later) is included at a bottom of a first-conductivity-type second diffusion region (P-type diffusion region 3), the N-type buried diffusion region formed by high energy implantation.

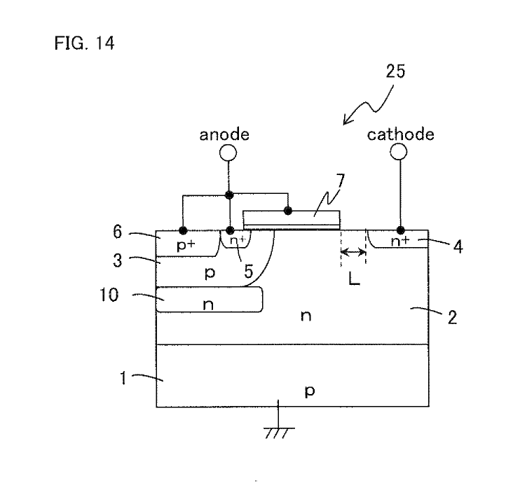

FIG. 14 is a longitudinal cross sectional view schematically illustrating an exemplary structure of an essential part of a high voltage diode, as a semiconductor apparatus according to Embodiment 5 of the present invention.

In FIG. 14, a high voltage diode 25 according to Embodiment 5 includes a characteristic structure of having an N-type buried diffusion region 10 formed by implanting high energy into the bottom side of a P-type diffusion region 3 in the N-type diffusion region 2, compared to the high voltage diode 21 according to Embodiment 1.

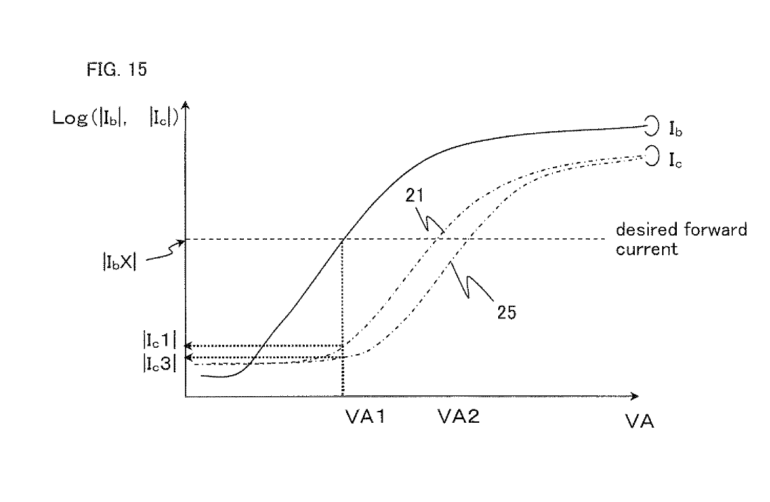

FIG. 15 illustrates the relationship between the anode voltage (V_{A}) and the forward current I_{b} as well as the relationship between the anode voltage (V_{A}) and the substrate leakage current I_{c} in Embodiments 1 and 5.

According to Embodiment 5, with regard to the parasitic PNPTr constituted of the P-type diffusion region 3 (emitter), the N-type diffusion region 2 (base), and the P-type semiconductor substrate 1, the provision of the N-type buried diffusion region 10 decreases the hFE of the parasitic PNPTr. As a result, as illustrated in FIG. 15, the substrate leakage current (I_{c}) to the P-type semiconductor substrate under a forward bias can be further decreased, compared to the case in Embodiment 1 (I_{c1}→I_{c3}).

Further, as previously mentioned, it is apparent that a decrease in the forward voltage (VF) and a decrease in the reverse recovery time are also feasible in Embodiment 5.

According to Embodiment 5 as described above, in the high voltage diode 25, the N-type buried diffusion region 10 is formed only on the bottom side of the P-type diffusion region 3, which allows further effective suppressing of the substrate leakage current during a forward bias operation and allows the forming to be done at a low cost, without having an epitaxial layer or a high concentration buried diffusion region as is done conventionally.

It is apparent that the same effect can be obtained by additionally forming the N-type buried diffusion region 10 in any of the high voltage diodes 21 to 24 according to Embodiments 1 to 4.

Next, a method for manufacturing the high voltage diode 24 with the structure described above will be described.

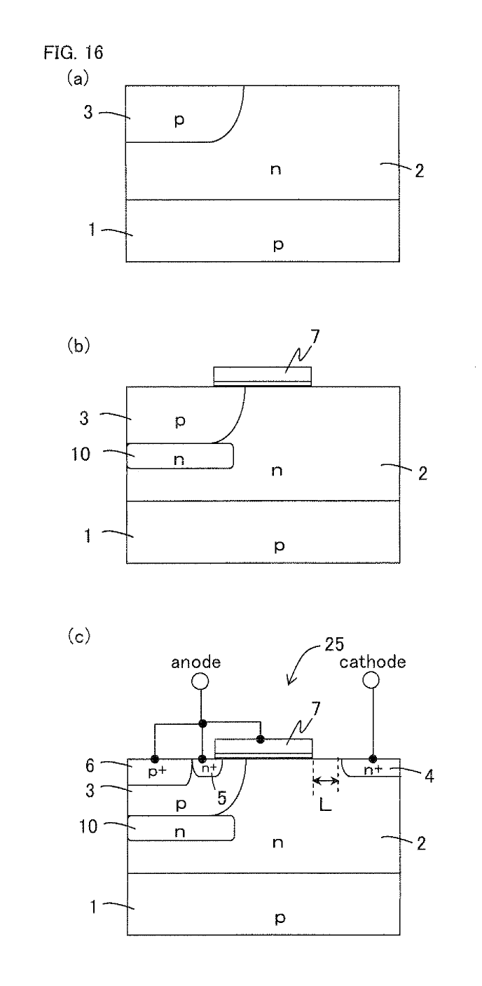

FIGS. 16(a) to 16(c) each are longitudinal cross sectional views of an essential part, for describing each manufacturing step in a method for manufacturing the high voltage diode 25 in FIG. 14.

As illustrated in FIG. 16(a), an N-type diffusion region 2 is first formed in a P-type semiconductor substrate 1 by implanting N-type impurities, such as phosphorus. Further, a P-type diffusion region 3 is formed in the N-type diffusion region 2 by implanting P-type impurities, such as boron.

Next, as illustrated in FIG. 16(b), an N-type buried diffusion region 10 is formed at a bottom of the P-type diffusion region 3 by high energy implantation. Phosphorus, for example, is used for the impurity implantation into the N-type buried diffusion region 10. The implantation energy is, for example, 800 KeV or more, and the dose is 1.0×10¹² cm⁻² or more.

Subsequently, as illustrated in FIG. 16(b), a gate insulation film is formed on a surface region of the N-type diffusion region 2 and a P-type diffusion region 3. On the gate insulation film, a gate electrode 7 is formed in such a manner that the gate electrode 7 stretches over to the N-type diffusion region 2 side from a part of the P-type diffusion region 3. For the material of the gate electrode 7, a polysilicon film in which phosphorus is doped, for example, is formed by CVD. A resist is patterned on the polysilicon film by a photoetching technique, and subsequently, the polysilicon film is processed into a given shape by a dry etching technique or the like to form the gate electrode 7.

Subsequently, as illustrated in FIG. 16(c), a high concentration N-type diffusion region 4 and a high concentration N-type diffusion region 5 are formed by impurity implantation of phosphorus or arsenic, for example. Also, by impurity implantation of boron, for example, a high concentration P-type diffusion region 6 is formed.

At this stage, the high concentration N-type diffusion region 5 is formed in a self-aligned manner with respect to the gate electrode 7, and thermal processing is also provided. Therefore, the gate electrode 7 is always formed overlapping the high concentration N-type diffusion region 5.

Further, an oxide film is formed on the surface by atmospheric pressure CVD, for example, and the difference in levels on the surface is reduced by reflow. Subsequently, contact etching is performed on the previously-mentioned oxide film above the gate electrode 7, the high concentration N-type diffusion region 5 and the high concentration P-type diffusion region 6 as well as above the high concentration N-type diffusion region 4, to form an opening. Further, an aluminum film is formed by sputtering, for example, and subsequently, the aluminum film is patterned by photoetching and dry etching to form a metal electrode.

At this stage, the high concentration N-type diffusion region 5, high concentration P-type diffusion region 6 and the gate electrode 7 are electrically connected with one another by the metal electrode at the same potential.

As described above, the high voltage diode 25 according to Embodiment 5 with a reverse bias MOSFET (Q1) is formed in the P-type semiconductor substrate 1.

In summary, the method for manufacturing the high voltage diode 25 according to Embodiment 5 includes: a step of forming the N-type diffusion region 2 in the P-type semiconductor substrate 1; a step of forming the P-type diffusion region 3, and of forming the N-type buried diffusion region 10 at the bottom of the P-type diffusion region 3 by high energy implantation in the N-type diffusion region 2; a step of forming the high concentration N-type diffusion region 5 and the high concentration P-type diffusion region 6 in the P-type diffusion region 3, and the high concentration N-type diffusion region 4 at a position separated by a given distance away from the P-type diffusion region 3, in the N-type diffusion region 2; a step of forming the gate electrode 7 above and between the high concentration N-type diffusion region 5 and the high concentration N-type diffusion region 4, with a gate insulation film interposed therebetween, in such a manner that the gate electrode 7 is formed overlapping the high concentration N-type diffusion region 5 vertically; and a step of electrically connecting the gate electrode 7 with the high concentration N-type diffusion region 5 and the high concentration P-type diffusion region 6, at the same potential.

In Embodiment 5, the case has been described where the N-type buried diffusion region 10 with high energy implantation is newly provided at the bottom of the P-type diffusion region 3 of the high voltage diode 21 in Embodiment 1; however, without limitation to this case, the N-type buried diffusion region 10 with high energy implantation may be newly provided at the bottom of the P-type diffusion region 3 of any of the high voltage diodes 22 to 24 in Embodiments 2 to 4. Also in this case, the provision of the N-type buried diffusion region 10 decreases the hFE of the parasitic PNPTr. Therefore, compared to the case of Embodiments 2 to 4, it allows further decreasing of the substrate leakage current (I_{c}) to the P-type semiconductor substrate 1 under a forward bias.

### Embodiment 6

In Embodiments 1 to 5, the case has been described where a first-conductivity-type semiconductor layer is a first-conductivity-type semiconductor substrate (P-type semiconductor substrate 1), and the high voltage diodes 21 to 25 are formed in the P-type semiconductor substrate 1. In Embodiment 6, a case will be described where a first-conductivity-type semiconductor layer is a first-conductivity-type diffusion region, and a high voltage diode 26 is formed on the P-type diffusion region.

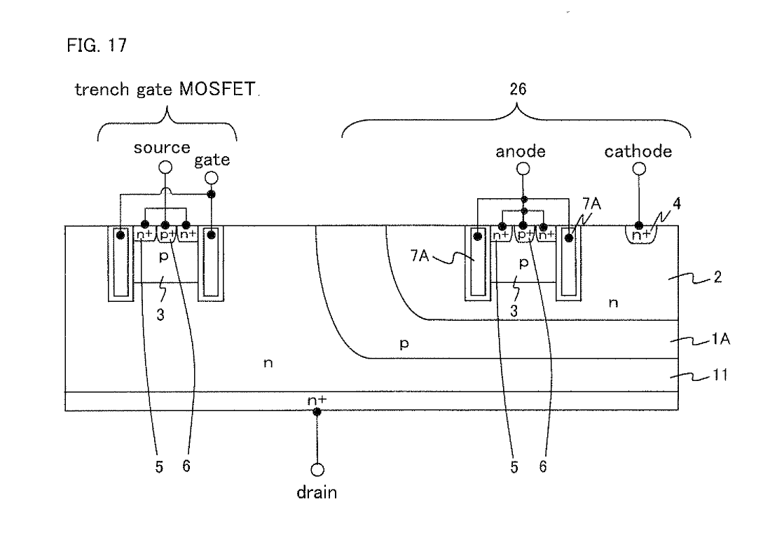

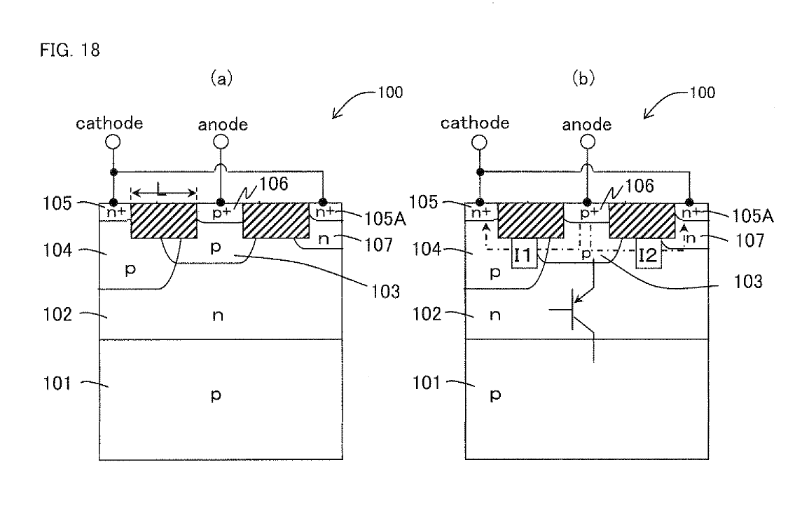

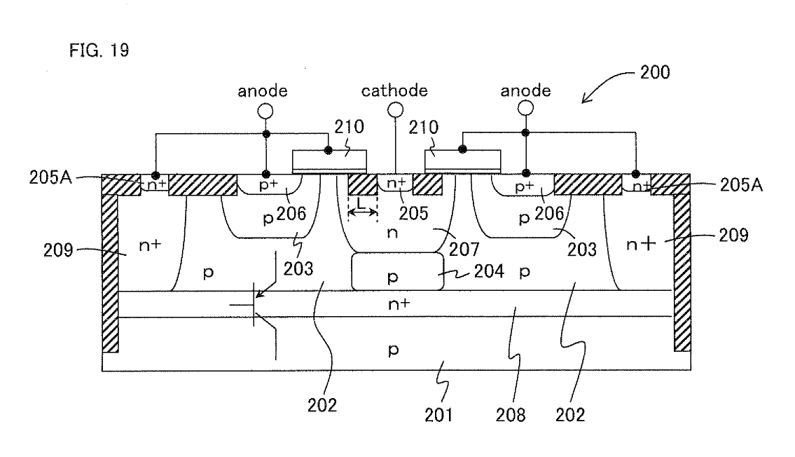

FIG. 17 is a longitudinal cross sectional view schematically illustrating an exemplary cross sectional structure of an essential part of a high voltage diode, as a semiconductor apparatus according to Embodiment 6 of the present invention.

As illustrated in FIG. 17, the high voltage diode 26 according to Embodiment 6 is different from the high voltage diodes 21 to 25 according to Embodiments 1 to 5, in that the high voltage diode 26 is formed in a P-type diffusion region 1A (e.g., a P well layer) on an N-type semiconductor substrate 11. For example, in a case of a process for mounting a trench gate MOSFET, the trench gate

MOSFET is a vertical-type semiconductor apparatus, a rear surface electrode is a drain (n+), and the N-type semiconductor substrate 11 is used. For this reason, the high voltage diode 26 according to Embodiment 6 is formed, for example, in a P well layer, such as the P-type diffusion region 1A, for the purpose of electrical separation from the N-type semiconductor substrate 11.

While Embodiment 6 illustrates an example where a trench gate 7A as a gate electrode is used, the effect of decreasing the substrate leakage current to the N-type semiconductor substrate 11 obtained is exactly the same as in the case of Embodiment 1. To be more precise, since the trench gate 7A as a gate electrode is electrically connected with an anode electrode at the same potential, the threshold voltage Vth of a built-in reverse bias MOSFET can be greatly decreased by a substrate bias effect during a forward bias operation. As a result, a forward current greatly increases owing to the on-mode of the reverse bias MOSFET, and an anode voltage corresponding to a desired forward current substantially decreases, resulting in a large decrease in the substrate leakage current to the N-type semiconductor substrate 11.

Further, as previously mentioned, it is apparent that a decrease in the forward voltage (VF) and a decrease in the reverse recovery time are also feasible in Embodiment 6.

In Embodiments 1 to 6, the semiconductor apparatus formed in the F-type semiconductor substrate 1 includes the N-type diffusion region 2 in the F-type semiconductor substrate 1, and includes the P-type diffusion region 3 and the high concentration N-type diffusion region 4, at a position horizontally separated from the P-type diffusion region 3, in the N-type diffusion region 2. In addition, the high concentration N-type diffusion region 5 and the high concentration P-type diffusion region 6 are formed in the P-type diffusion region 3. The gate electrode 7 is formed above the N-type diffusion region 2 and the P-type diffusion region 3 and between the high concentration N-type diffusion region 5 and the high concentration N-type diffusion region 4, with a gate oxide film interposed therebetween. The gate electrode 7 is formed overlapping the high concentration N-type diffusion region 5. Further, the high concentration P-type diffusion region 6, the high concentration N-type diffusion region 5 and the gate electrode 7 in the anode region are electrically connected with one another at the same potential.

According to Embodiments 1 to 6 as described above, in the high voltage diodes 21 to 26, the effective suppressing of the substrate leakage current during a forward bias operation and the forming at a low cost are allowed, without having an epitaxial layer or a high concentration buried diffusion region as is done conventionally. Further, a decreasing of the forward voltage (VF) and a decreasing of the reverse recovery time are allowed.

In Embodiment 1, the case has been described where: the N-type diffusion region 2 is formed in the P-type semiconductor substrate 1 as a semiconductor layer; the P-type diffusion region 3 is formed in the N-type diffusion region 2; the high concentration N-type diffusion region 5 and the high concentration P-type diffusion region 6 are formed in the P-type diffusion region 3; the high concentration N-type diffusion region 4 is formed at a position separated from the P-type diffusion region 3 in the N-type diffusion region 2; and the gate electrode 7 is formed above and between the high concentration N-type diffusion region 5 and the high concentration N-type diffusion region 4 with a gate insulation film interposed therebetween, in which the gate electrode 7 is formed overlapping the high concentration N-type diffusion region 5, and the gate electrode 7 is electrically connected with the high concentration N-type diffusion region 5 and the high concentration P-type diffusion region 6 at the same potential. In Embodiment 2, the case has been described where: in addition to the case in Embodiment 1, the N-type diffusion region 8 and the P-type diffusion region 3 are in the N-type diffusion region 2; and the high concentration N-type diffusion region 4 is in the N-type diffusion region 8. In Embodiment 3, the case has been described where: in addition to the case in Embodiment 1, the insulation separation film 9 and the P-type diffusion region 3 are formed in the N-type diffusion region 2. In Embodiment 4, the case has been described where: in addition to the case in Embodiment 1, the N-type diffusion region 8 is formed in the N-type diffusion region 2 in addition to the P-type diffusion region 3; and the insulation separation film 9 is in the N-type diffusion region 8, in which the insulation separation film 9 is formed between the P-type diffusion region 3 and the high concentration N-type diffusion region 4. In Embodiment 5, the case has been described where: in addition to the case in Embodiment 1, in addition to the P-type diffusion region 3, the N-type buried diffusion region 10 is formed by high energy implantation in the N-type diffusion region 2 at the bottom of the P-type diffusion region 3. While the P-type semiconductor substrate 1 as a semiconductor layer is used in the case of Embodiments 1 to 5, the case has been described where the P-type diffusion region 1A as a semiconductor layer is used in Embodiment 6. However, without limitation to this case, the conductivity types can all be reversed. In other words, there may be a case in Embodiment 1 where the conductivity types are all reversed, which includes: a P-type diffusion region formed on an N-type semiconductor substrate as a semiconductor layer; an N-type diffusion region formed in the P-type diffusion region; a high concentration P-type diffusion region and a high concentration N-type diffusion region formed in a N-type diffusion region; a high concentration P-type diffusion region formed at a position separated from the N-type diffusion region in the P-type diffusion region; and a gate electrode formed above and between the high concentration P-type diffusion region and the high concentration P-type diffusion region with a gate insulation film interposed therebetween, in which the gate electrode is formed overlapping the high concentration P-type diffusion region, and the gate electrode is electrically connected with the high concentration P-type diffusion region and the high concentration N-type diffusion region at the same potential. In Embodiment 2, there may be a case where the conductivity types are all reversed and includes a P-type diffusion region, in addition to the N-type diffusion region, are formed in the P-type diffusion region; and the high concentration P-type diffusion region in the P-type diffusion region. In Embodiment 3, there may be a case where the conductivity types are all reversed and includes an insulation separation film in addition to the N-type diffusion region, formed in the P-type diffusion region. In Embodiment 4, there may be a case where the conductivity types are all reversed and includes: a P-type diffusion region formed in the P-type diffusion region in addition to the N-type diffusion region; and the insulation separation film is formed in the P-type diffusion region, in which the insulation separation film is formed between the N-type diffusion region and the high concentration P-type diffusion region, In Embodiment 5, there may be a case where the conductivity types are all reversed and it includes: in addition to the N-type diffusion region, a P-type buried diffusion region is formed by high energy implantation in the P-type diffusion region at the bottom of the N-type diffusion region. In the case of Embodiments 1 to 5, the conductivity types may be all reversed and an N-type semiconductor substrate as a semiconductor layer may be used In Embodiment 6, an N-type diffusion region as a semiconductor layer may be used.

As described above, the present invention is exemplified by the use of its preferred Embodiments 1 to 6. However, the present invention should not be interpreted solely based on Embodiments 1 to 6 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 6 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a semiconductor apparatus, such as a high voltage diode, which is a device for rectification; and a method for manufacturing the semiconductor apparatus. According to the present invention, the effective suppressing of the substrate leakage current during the forward bias operation is allowed, without having an epitaxial layer or a high concentration buried diffusion region, thereby forming the present invention at a low cost. Further, a decreasing of a forward voltage (VF) and a decreasing of a reverse recovery time are allowed.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A semiconductor apparatus formed on a first-conductivity-type semiconductor layer the semiconductor apparatus comprising:
a second-conductivity-type first diffusion region formed on the semiconductor layer;
a first-conductivity-type second diffusion region formed in the first diffusion region;
a second-conductivity-type first high concentration diffusion region and first-conductivity-type second high concentration diffusion region formed in the second diffusion region;
a second-conductivity-type third high concentration diffusion region, formed at a position separated by a given distance away from the second diffusion region, in the first diffusion region; and
a gate electrode formed above and between the first high concentration diffusion region and the third high concentration diffusion region, with a gate insulation film interposed therebetween,
wherein the gate electrode is formed overlapping the first high concentration diffusion region, and the gate electrode is electrically connected with the first high concentration diffusion region and the second high concentration diffusion region, at the same potential.

2. A semiconductor apparatus according to claim 1, wherein the first high concentration diffusion region, the third high concentration diffusion region, and the gate electrode provided therebetween constitute a reverse bias MOSFET.

3. A semiconductor apparatus according to claim 1, wherein one end of the gate electrode is separated by a given distance from the third high concentration diffusion region.

4. A semiconductor apparatus according to claim 1, wherein the first high concentration diffusion region, the second high concentration diffusion region, and the gate electrode are connected with an anode electrode, and the third high concentration diffusion region is connected with a cathode electrode.

5. A semiconductor apparatus according to claim 1, wherein a second-conductivity-type third diffusion region is included in the second-conductivity-type first diffusion region, and the third high concentration diffusion region is included in the third diffusion region.

6. A semiconductor apparatus according to claim 1, wherein an insulation separation film is included in the second-conductivity-type first diffusion region, the insulation separation film formed between the first-conductivity-type second diffusion region and the third high concentration diffusion region.

7. A semiconductor apparatus according to claim 1, wherein a second-conductivity-type third diffusion region is included in the second-conductivity-type first diffusion region; the third high concentration diffusion region and the insulation separation film are included in the third diffusion region; and the insulation separation film is formed between the first conductivity-type second diffusion region and the third high concentration diffusion region.

8. A semiconductor apparatus according to claim 5, wherein the second diffusion region and the third diffusion region are separated from each other by a given distance below the gate electrode.

9. A semiconductor apparatus according to claim 7, wherein the second diffusion region and the third diffusion region are separated from each other by a given distance below the gate electrode.

10. A semiconductor apparatus according to claim 7, wherein the second diffusion region and the insulation separation film are separated from each other by a given distance below the gate electrode.

11. A semiconductor apparatus according to claim 6, wherein the insulation separation film is provided for a given length including a lower end of the gate electrode on the side closer to the third high concentration diffusion region.

12. A semiconductor apparatus according to claim 7, wherein the insulation separation film is provided for a given length including a lower end of the gate electrode on the side closer to the third high concentration diffusion region.

13. A semiconductor apparatus according to claim 1, wherein a second-conductivity-type buried diffusion region formed by high energy implantation is included at a bottom of the first-conductivity-type second diffusion region.

14. A semiconductor apparatus according to claim 1, wherein the first-conductivity-type semiconductor layer is a first-conductivity-type semiconductor substrate.

15. A semiconductor apparatus according to claim 1, wherein the first conductivity type, semiconductor layer is a first conductivity type, diffusion region.

16. A semiconductor apparatus according to claim 1, wherein the semiconductor apparatus is a high voltage diode.

17. A method for manufacturing a semiconductor apparatus formed on a first-conductivity-type semiconductor layer, the method comprising:
a step of forming a second-conductivity-type first diffusion region on the semiconductor layer;
a step of forming a first-conductivity-type second diffusion region in the first diffusion region;
a step of forming a second-conductivity-type first high concentration diffusion region and a first-conductivity-type second high concentration diffusion region in the second diffusion region, and a second-conductivity-type third high concentration diffusion region, at a position separated by a given distance away from the second diffusion region, in the first diffusion region;
a step of forming a gate electrode above and between the first high concentration diffusion region and the third high concentration diffusion region, with a gate insulation film interposed therebetween, in such a manner that the gate electrode is formed overlapping the first high concentration diffusion region vertically; and
a step of electrically connecting the gate electrode with the first high concentration diffusion region and the second high concentration diffusion region, at the same potential.

18. A method for manufacturing a semiconductor apparatus according to claim 17, wherein the step of forming a first-conductivity-type second diffusion region in the first diffusion region includes a step of forming a second-conductivity-type third diffusion region in the first diffusion region, separated by a given distance away from the second diffusion region; and the step of forming a second-conductivity-type third high concentration diffusion region, at a position separated by a given distance away from the second diffusion region, in the first diffusion region, forms the third high concentration diffusion region in the third diffusion region, in the first diffusion region.

19. A method for manufacturing a semiconductor apparatus according to claim 17, wherein the step of forming a first-conductivity-type second diffusion region in the first diffusion region includes a step of forming an insulation separation film in the first diffusion region, separated by a given distance away from the second diffusion region.

20. A method for manufacturing a semiconductor apparatus according to claim 17, wherein:
the step of forming a first-conductivity-type second diffusion region in the first diffusion region includes a step of forming a second-conductivity-type third high concentration diffusion region, separated by a given distance away from the second diffusion region, in the first diffusion region, and of forming an insulation separation film, separated by a given distance away from the second diffusion region, in the third diffusion region; and
the step of forming a second-conductivity-type third high concentration diffusion region, at a position separated by a given distance away from the second diffusion region, in the first diffusion region, forms the third high concentration diffusion region in the third diffusion region, in the first diffusion region.

21. A method for manufacturing a semiconductor apparatus according to claim 17, wherein the step of forming a first-conductivity-type second diffusion region in the first diffusion region includes a step of forming a second-conductivity-type buried diffusion region, by high energy implantation, at a bottom of the second diffusion region.
